(19) United States
(12) Patent Application Publication
(10) Pub. No.: US 2010/0194444 A1
(43) Pub. Date: Aug. 5, 2010

(54) REDUCTION OF SPURIOUS FREQUENCY COMPONENTS IN DIRECT DIGITAL SYNTHESIS

(75) Inventor: Jeffery Patterson, Cloverdale, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(73) Assignee: AGILENT TECHNOLGIES, INC, Loveland, CO (US)

(21) Appl. No.: 12/363,660

(22) Filed: Jan. 30, 2009

(51) Int. Cl. H03B 21/00

(52) U.S. Cl. 327/106

(57) ABSTRACT

In an embodiment, an apparatus, comprises a phase accumulator configured to provide an output comprising a truncated phase word representative of an instantaneous phase; a multiplexer configured to provide an output representative of a phase rotation, wherein the output representative of the phase rotation is randomly selected from a group of phase rotation representation outputs; an adder configured to receive the output from the phase accumulator and the output from the multiplexer, wherein the adder provides an output representative of the instantaneous phase rotated by the phase rotation; a lookup table configured to receive the output representative of the instantaneous phase and to provide an amplitude output; and a rotator configured to receive the amplitude output and substantially to cancel the phase rotation. Other embodiments do not comprise a rotator. A method is also described.

### BACKGROUND

Numerically controlled oscillators (NCOs) for use in direct digital synthesis (DDS) are used to generate signals at a specific frequency for a variety of uses such as in communication devices (e.g., telephones and mobile handsets) and testing devices (e.g., signal generators). Among other goals, DDS aims to provide a comparatively highly spectrally pure signal.

FIG. 1 shows a known NCO 100, which comprises a phase accumulator 101, which comprises an adder 102 and delay element 103. The phase accumulator 101 provides outputs to first lookup table 104 and a second look up table 105. The first lookup table 104 stores amplitude values of a sinusoidal wave for phase values at its input, and the second lookup table 105 stores amplitude values for a cosinuisoidal wave. These lookup tables are often referred to as phase-to-amplitude converters, as their respective outputs provide sine and cosine amplitudes of signals for a given phase domain input value.

In generating the digital representation of the sinusoidal wave or cosinusoidal wave, an input signal 106 is received at NCO 100. The input signal 106 is a ratio of a desired frequency (f₀) of the output divided by a clock frequency (f_{clk}) of the system. This ratio provides the phase step for each clock cycle of the system (e.g., a ratio of 0.1 is indicative of a 36 degree angle change along the wave for every clock cycle of the system). The input signal 106 passes through phase accumulator 101. As is known, the output of the phase accumulator 101 determines the phase of a signal at a given instant of time. The phase accumulator 101 adds 360(f₀/f_{clk}) degrees of phase to signal 106 for every instant of time. At a time interval of once every 1/f_{clk} seconds, the adder 102 receives the value of the output from the delay element 103 and adds that value to the current value. After one full cycle of phase is accumulated (corresponding to 2π radians), the accumulator overflows and a new cycle begins starting from the residual remainder stored in the delay element 103. The lookup tables 104, 105 converts the phase domain representation contained at the output of the phase accumulator 101 into sinusoidal and cosinusoidal signals in the amplitude domain, to provide quadrature signals at the output of the DDS.

As noted, the lookup tables 104, 105 comprise a direct correlation between the phase value and the amplitude of the signal, thereby providing a digital representation of the desired signal. In order to provide an analog signal (sine or cosine wave) that is spectrally substantially pure based on the digital representation thereof, a comparatively large number of phase values must be garnered and stored in the look up tables 104, 105. In order to avoid having to provide unmanageably large data values in the lookup tables 104, 105 and the required processing thereof, truncating of the data is often effected. While useful in reducing the memory and processor requirements, truncating the number of data values stored in the lookup tables 104, 105 can cause errors that are manifest in both phase and amplitude errors in the synthesized signal. The errors due to truncation of phase and amplitude are repetitive and result in spurious signals (commonly referred to as spurs) at certain frequencies. As should be appreciated, these spurs degrade the purity of the synthesized signal.

What is needed, therefore, is a method and apparatus for reducing spurs in DDS signals that overcome at least these drawbacks of known devices and methods described above.

### BRIEF DESCRIPTION OF THE DRAWINGS

The present teachings are best understood from the following detailed description when read with the accompanying drawing figures. The features are not necessarily drawn to scale. Wherever practical, like reference numerals refer to like features.

FIG. 1 is a block diagram of a phase accumulator and look up tables of a known DDS.

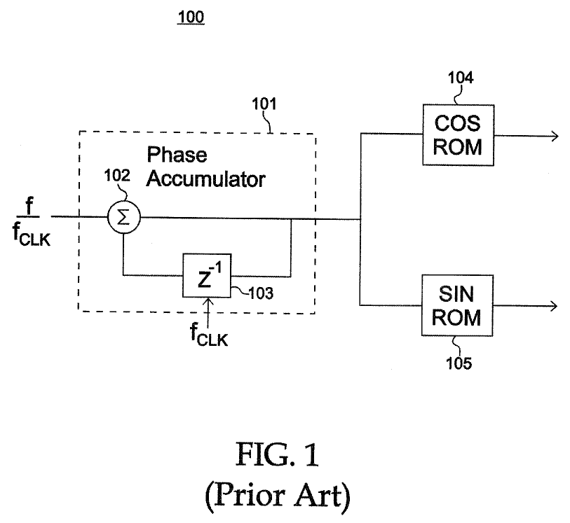

FIG. 2 shows a simplified block diagram of an apparatus for DDS in accordance with a representative embodiment.

FIG. 3 shows a phasor diagram showing rotation and counter-rotation of a phasor representative of an amplitude of a signal synthesized in accordance with a representative embodiment.

FIG. 4 shows a simplified block diagram of an apparatus for DDS in accordance with a representative embodiment.

FIG. 5A is a graphical representation of a signal (power relative to the carrier (dBc) versus frequency) of a signal synthesized using a known DDS apparatus.

FIG. 5B shows a frequency spectrum of a DDS signal synthesized using a DDS method and apparatus in accordance with a representative embodiment.

FIG. 6A is a graphical representation of a signal (power relative to the carrier (dBc) versus frequency) of a signal synthesized using a known DDS apparatus.

FIG. 6B shows a frequency spectrum of a DDS signal synthesized using a DDS method and apparatus in accordance with a representative embodiment.

### DEFINED TERMINOLOGY

It is to be understood that the terminology used herein is for purposes of describing particular embodiments only, and is not intended to be limiting.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, in addition to their ordinary meanings, the terms ‘substantial’ or ‘substantially’ mean to with acceptable limits or degree to one having ordinary skill in the art. For example, ‘substantially cancelled’ means that one skilled in the art would consider the cancellation to be acceptable.

In addition to its ordinary meaning, the term ‘approximately’ means to within an acceptable limit or amount to one having ordinary skill in the art. For example, ‘approximately the same’ means that one of ordinary skill in the art would consider the items being compared to be the same.

### DETAILED DESCRIPTION

In the following detailed description, for purposes of explanation and not limitation, representative embodiments disclosing specific details are set forth in order to provide a thorough understanding of the present teachings. Descriptions of known systems, devices, materials, methods of operation and methods of manufacture may be omitted so as to avoid obscuring the description of the example embodiments. Nonetheless, systems, devices, materials and methods that are within the purview of one of ordinary skill in the art may be used in accordance with the representative embodiments. The detailed description which follows presents methods that may be embodied by routines and symbolic representations of operations of data bits within a computer readable medium, associated processors, microprocessors, digital storage oscilloscopes, general purpose personal computers, manufacturing equipment, configured with data acquisition cards and the like. In general, a method herein is conceived to be a sequence of steps or actions leading to a desired result, and as such, encompasses such terms of art as “routine,” “program,” “objects,” “functions,” “subroutines,” and “procedures.”

The apparatuses and methods of the illustrative embodiments are described in implementations in a measurement system including one or more testing devices (e.g., signal generators/sources, spectrum analyzers, and ‘one-box-testers’ (OBTs)). Machines that may perform the test functions according to the present teachings include those manufactured by companies such as AGILENT TECHNOLOGIES, INC., TEKTRONIX, INC., FLUKE CORPORATION, NATIONAL INSTRUMENTS, INC., as well as other manufacturers of test and measurement equipment.

The methods and apparatuses are presented in representative embodiments used in electromagnetic signal generation, generally. In specific embodiments, the NCOs for DDS are used in signal generators for test and measurement equipment. However, the NCOs of the representative embodiments are contemplated for many other applications. Illustratively, the NCOs of the representative embodiment may be used in radio frequency (RF) handsets, chipsets, base-stations and receiver/transmitter hardware thereof. For instance, the NCOs may be used in place of known phase locked loops (PLL) in both signal modulation/transmission and signal demodulation/reception. Still the apparatuses, methods, and systems of the present teachings are more broadly applicable. For illustrative purposes, it is contemplated that the present teachings are contemplated for use in many disparate to signal generation applications. For example, the methods and apparatuses of the present teachings are contemplated for use in signal generation for both signal transmission and reception in communication devices and systems (e.g., mobile telephone communications), radio direction and ranging (radar), and global positioning systems (GPS).

The NCOs of the representative embodiments are instantiated in hardware either in component form or as an integrated circuit, For example, the NCOs may be application specific integrated circuits (ASICs), or may be included in a chip set, Field Programmable Gate Array (FPGA) or other IC as may be desired. It is contemplated that the NCOs be instantiated in silicon, and thereby processed using known methods and materials. The NCOs may also be instantiated in Group III-V semiconductors, such as GaₓAs₁₋ₓ, or InP for higher frequency applications. Moreover, applicants contemplate the use of programmable logic devices (PLDs) such as field programmable gate arrays (FPGAs) to instantiate all or part of the NCOs. Additionally, the use of software to effect a function of the NCOs, and/or to alter the function of the NCOs, and otherwise to control the NCOs is contemplated. Finally, the implementation of many if not all components of the NCOs of the present teachings entirely in software is contemplated.

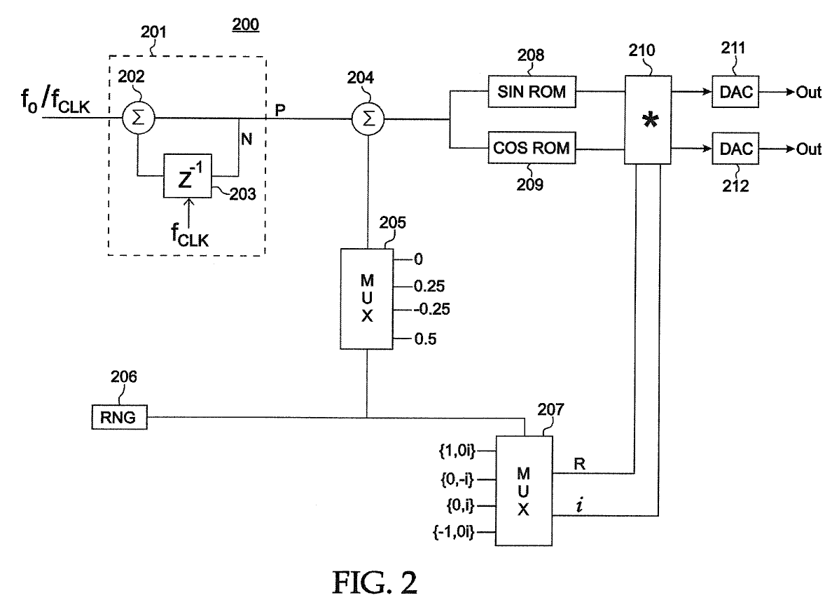

FIG. 2 shows a simplified block diagram of an NCO 200 for DDS in accordance with a representative embodiment. The NCO 200 comprises a phase accumulator 201, comprising a first adder 202 and a delay element 203, which advances at a selected clock frequency, f_{clk}. The NCO 200 also comprises a second adder 204 at the output of the phase accumulator 201. The second adder 204 adds the output from the phase accumulator 201 with an output from a first multiplexer (mux) 205 as described more fully below. The NCO 200 also comprises a random number generator (RNG) 206, which provides an output to the first mux 205 and to a second mux 207 as described more fully below.

In the present representative embodiment, the NCO 200 comprises a sine look up table (s-LUT) 208 and a cosine lookup table (c-LUT) 209, which are illustratively read only memory (ROM) devices. The output of the s-LUT 208 and the c-LUT 209 are provided to a rotator 210. The rotator 210 comprises a known complex multiplier, which may be instantiated as a core in an FPGA of the NCO 200, for example. The rotator 210 receives another input from the second mux 207 for reasons described more fully below. The respective outputs of the rotator 210 are provided a first digital to analog converter (DAC) 211 and a second DAC 212, which create time varying, analog waves. In the present embodiments, the output is a quadrature output, such as quadrature modulation (e.g., QAM) of one wave by another. Notably, the outputs from the rotator 210 and to the DAC need not be a quadrature output, in which case only one output of the complex multiplier (rotator) would be forwarded to its respective DAC. Notably, the NCO 200 requires both the s-LUT 208 and the c-LUT 209 even if a single analog output is all that is provided. In the present embodiment, which comprises rotator 210, the outputs of both LUTs are provided to the rotator 210 and only one of the two outputs is passed to the DAC. In an embodiment described below, only a single output multiplexer would be required to effect a single analog output.

The phase accumulator 201 receives an input of f₀/f_{clk} and incrementally indexes the value with each indexing of the delay element 203, which indexes at the clock rate f_{clk}. The phase accumulator 201 is configured to store a fixed number (e.g., N bits) of phase values for each complete cycle of phase (2π radians), whereupon the adder 202 overflows, with the carry bit(s) being discarded and the sequence continues. Ideally, there would be a comparatively large number of bits carried in the phase accumulator 201 governed by the bit width of the delay element and the adder to provide a substantially high frequency resolution after conversion by the DACs 211 and 212. Moreover, absent correction, spectral purity is determined by the number of bits available in the ROM, which is governed by the number of elements stored therein and the data width (in bits) of each element. However, as noted above, there are practical limits to storing and processing large bits numbers, so a truncation of the phase accumulator output phase value is required. As such, at each sample of f_{clk}, the output of the phase accumulator (shown as P in FIG. 2) is truncated to a value having P bits, where N>P. Thus, rather than the N bit word (shown as N in FIG. 2) that is feedback to adder 202 through delay element 203, a truncated P bit word is provided from the accumulator to the second adder 204. Graphed versus time, the output of the phase accumulator is a saw-tooth function with a linear-fit about the truncated phase values, with a slope equal to the normalized frequency f₀/f_{clk}. Because the phase values are truncated, a phase error results from selection of the closest value of phase for a given sample of f_{clk}. This truncation error gives rise to spurious signals that can be substantially mitigated by adding random dither noise to the phase prior to truncation by known methods.

For each incremental P-bit phase word (P<N) output from the phase accumulator 201, there is a corresponding amplitude value stored in the look up tables 208, 209. The desired output signal is created by using each P-bit phase word output from phase accumulator 203 to access the corresponding amplitude value stored in the ROM. From this phase to amplitude conversion and after subsequent digital-to-analog conversion and suitable reconstruction, a signal having frequency f₀=dφ/dt can be garnered, where f₀/f_{clk} corresponds to one of 2^{N} possible values.

In addition to the phase truncation error described above, amplitude truncation error is another error source that also gives rise to spurious signals at the output of the NCO 200. Amplitude truncation errors are due to the necessity of truncating the transcendental value of the sinusoids of a given phase to a value which can be represented in the number of bits allocated to each word stored in the ROM. Stated somewhat differently, the transcendental values of the sinusoids are ‘rounded off’ due to the bit allocation in the ROM. Unfortunately, unlike phase truncation errors, amplitude truncation errors are fixed in the binary representations of these transcendental values and are therefore not amenable to the addition of dither noise by known techniques. In particular, adding enough dither noise at the input of the LUTs 208, 209 to prevent the errors due to amplitude truncation from being accessed repetitively would result in an undesirable degradation in phase noise, while adding dither at the output would occur post truncation and hence not mitigate the spurious but merely add noise to them.

Because the output of phase accumulator 201 is periodic when provided constant normalized frequency f₀/f_{clk}, the accessing of the stored values in the ROMs 208, 209 is also periodic under continuous wave (CW) conditions. As such, the amplitude truncation error inherent in the values accessed by the ROMs repeats and is manifest as spurious signals (spurs). As should be appreciated, these spurs have a deleterious impact on the spectral output of the NCO 200. As will become clearer as the present description continues, according to representative embodiments, these deleterious effects are mitigated by introducing large scale randomization in the phase domain which substantially prevents the periodic accessing of the fixed truncation error. The otherwise deleterious effect of the randomizing phase signal is then substantially cancelled at the NCO output by the counter-rotation of the instantaneous output phase in the amplitude domain by an amount equivalent to the input phase rotation provided by a dither signal in the phase domain.

In accordance with the present teachings described more fully presently, random spurs due to finite arithmetic effects in the look up tables 208, 209 are substantially eliminated by random rotation in the phase domain and corresponding counter rotation in the amplitude domain. In a representative embodiment, the RNG 206 provides an output to the first mux 205 and the second mux 207. The instantaneous phase value provided by the phase accumulator 201 to the second adder 204 represents the phase of the desired signal at a particular sample of a clock signal. This phase value is added to the random value of the first mux 205, and the output of the adder represents a phase value that is altered. In the present embodiment, once per clock cycle, the phase value input to the second adder 204 is incremented by one-quarter cycle (±0.25), is unchanged, or is incremented by one half cycle (0.5) as determined by the output of RNG 206 indexing one of the fixed rotations provide by the first mux 205. Notably, the outputs of the first mux 205 (±0.25, 0 or 0.5) are representative. Greater randomization of the error can be achieved by selecting of a greater number of fractional cycles resulting in a further reduction of the spurious content at the output. Regardless, any underflow or overflow from this operation can be discarded without effect because the underflow or overflow represent one full cycle of phase advance or retard and have no impact on the trigonometric value obtained from the look up tables 208, 209. The output of the second adder 204 is provided to the lookup tables 208, 209, which provide an amplitude output value for the altered instantaneous phase value provided. Optionally, the instantaneous phase value may comprise a functional phase-to-phase transformation providing filtration, or interpolation functionality, or both for example to improve throughput. This is effected, for example using known phase transformers (not shown). In a representative embodiment, a single phase accumulator (e.g., phase accumulator 201) is configured to drive a phase interpolator, which provides a functional transform. In turn, the phase interpolator provides multiple separate outputs to multiple separate LUT's each of which contains own spur elimination circuit in accordance with the representative embodiments. Alternatively, a DSP (not shown) could be instantiated between the phase accumulator 201 and the LUTs to effect this functional transformation.

Because of the random rotation of the input phase, the amplitude values output to the DAC from the lookup tables 208, 209 correspond to an amplitude of the signal at the altered phase. However, the value from the RNG 206 provided to the second mux 207 selects the output of the second mux 207 to be a counter-rotation of equal magnitude in phase. In particular, the output of the second mux 207 is provided to the rotator 210, which as described more fully below, multiplies the rotated phase vector by a counter phase vector, and rotates the phase vector back by an equal magnitude. As should be appreciated by one of ordinary skill in the art, peaks in the autocorrelation of the sinusoidal truncation error function will have a deleterious impact on the effectiveness of the spur reduction technique of the present teachings. Known steps to mitigate the autocorrelation peaks include, but are not limited to, randomly rounding the transcendental value prior to truncation, or providing a small phase offset prior to truncation. However, as described presently, the phase error sequence at the output of the NCO is randomized and thus likely not periodic. As such, while the truncation errors are fixed, the order in which these errors are accessed is randomized and is therefore substantially not periodic.

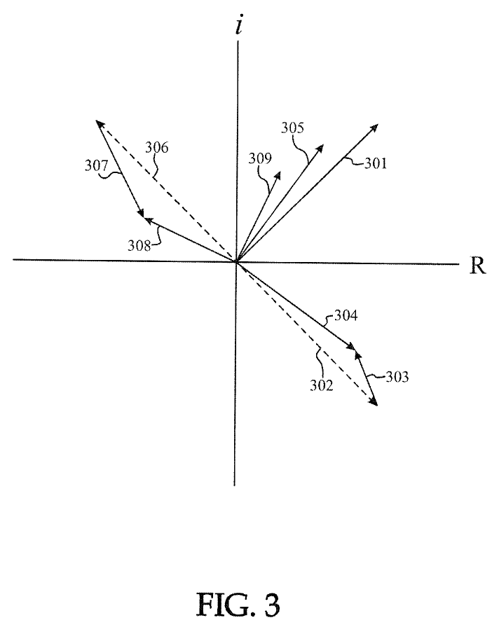

FIG. 3 shows a phasor diagram showing rotation and counter-rotation of a phaser representative of an amplitude of a signal synthesized in accordance with a representative embodiment. The phasor diagram is useful in clarifying the randomizing of phase error in keeping with the representative embodiments. At an instant in time, the output of the phase accumulator can be represented as a complex vector having an instantaneous angular velocity that is the first derivative with respect to time of the phase value from the phase accumulator. For example, phase vector (phasor) 301 represents the amplitude and phase of the desired signal at an instant in time. As noted, the phase error due to truncation provides an error value for the selected phase. To mitigate this effect, the phasor 301 is rotated by a randomly selected quarter cycle as provided by the first mux 205. In the present example, the rotation is +π/2 radians. This rotation results in phasor 302, which is rotated by +90° relative to phasor 301. The error value of the phase error at this rotated phase is shown as 303, and is added to the phasor 302 to provide phasor 304 as the output from the look up tables 208, 209. Notably, the magnitude of the phasor 303 is grossly exaggerated to allow for a visual explanation. With the counter-rotation value from the second mux 207, the rotator 210 rotates by in an opposite sense resulting in phasor 305, so that phasor 305 is rotated by −90° relative to phasor 304. In the present example, the second mux 207 provides an output {0, −i} to the rotator 210. The multiplying of the output {0, −i} by phasor 304 results in phasor 305. It is noted that the magnitude of phasor 305 is likely not identical to the magnitude of phasor 301, but rather is governed by the magnitude and orientation of the phasor 304 that is representative of the amplitude truncation error.

At another instant in time, the phase value output by the phase accumulator 201 again results in phasor 301. However, in this instance, the first mux 205 provides a rotation value of minus one-quarter cycle (i.e., −0.25), and a phasor 306 results, which is rotated by −90° relative to phasor 301. The phase error for the phase value after rotation is represented as phasor 307, and results in phasor 308 as the output of the lookup tables 208, 209. Again, the magnitude of the phasor 307 is grossly exaggerated to allow for a visual explanation. With the counter-rotation value from the second mux 207, the rotator 210 rotates in an opposite sense resulting in phasor 309, which is rotated by +90° relative to phasor 308. In the present example, the second mux 207 provides an output {0, +i}, which when multiplied by phasor 308 provides phasor 309. As such, for the phase value that provides phasor 301 in two separate instants in time, rather than having a resultant phasor with a phase error that will repeat, the resultant phase error is randomized in the form of phasors 305, 309. It is noted that the magnitude of phasor 307 is likely not identical to the magnitude of phasor 301, but rather is governed by the magnitude and orientation of the phasor 308 that is representative of the amplitude truncation error.

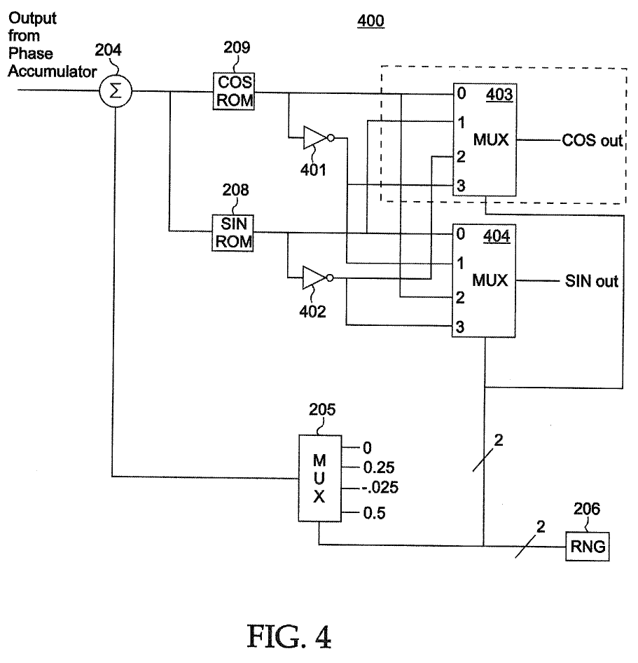

As noted previously, the output to the DAC 211 does not have to be quadrature. Moreover, a rotator may be foregone, and its operation done using muxes. FIG. 4 shows a block diagram of an NCO 400 for DDS in accordance with a representative embodiment, where a rotator is not included. Notably, many of the details and principles described in conjunction with embodiments of FIGS. 2 and 3 are common to the presently described embodiments. Such common details and principles are not repeated in order to avoid obscuring the presently described embodiments.

NCO 400 comprises the phase accumulator 201 (not shown in FIG. 4), second adder 204, first mux 205, RNG 206, sine ROM 208 and cosine ROM 209. The ROMs 208, 209 are connected selectively to a cos mux 401 and a sine mux 402 as shown. The NCO 400 also comprises a first inverter 403 and a second inverter 404 connected as shown.

The output from the phase accumulator is provided to the second adder 204 as described previously. The first mux 205 provides a rotational value based on input from the RNG 206. The RNG 206 also provides this input to the muxes 401, 402. With the mux inputs 0, 1, 2, 3 as shown for a phase input α:

| | Phase | |
|---|---|---|
| RNG | Input | |
| Output | to LUT | Output |
| 0 | α | Cos(α) + j Sin(α) |
| 1 | α + π/2 | Sin(α + π/2) − jCos(α + π/2) = Cos(α) + jSin(α) |
| 2 | α − π/2 | −Sin(α − π/2) + jCos(α − π/2) = Cos(α) + jSin(α) |
| 3 | −α | −Cos(−α) − jSin(−α) = Cos(α) + jSin(α) |

The real portion of the complex output is the output of the cos mux 401 and the imaginary part is the output of the sin mux 402. As can be seen from the known trigonometric expansions of the Output column of the table above, the required amplitude domain counter-rotation necessary for substantially cancelling the effects of the phase domain rotational dither is provided by the comparatively simple mathematical operations indicated. Moreover, if additional randomization is desired, it can be achieved with a similar expansion technique although the mathematical operations required for cancellation will be more complex. Notably, in the embodiment in which the rotation is by one of 0, ±π/2, π, by known trigonometric identities, the above rotations occur. Additional randomization would result from providing other phase inputs to the LUTs and use of known trigonometric expansions to derive the output. While more complicated, additional randomization may be useful in certain situations. It is noted that while both the values from both the sine ROM 208 and the cosine ROM 209 are needed to implement the randomization of the amplitude truncation error according to the present teachings, it is often desired to provide only a sinusoidal or a cosinusoidal output. Effecting this output merely requires selecting the output from the desired MUX to be transmitted to the DAC (not shown). Alternatively, in certain embodiments where only the sinusoidal or cosinusoidal output is needed, the desired MUX is implemented and the undesired MUX is foregone. For example, in an implementation in which only the sinusoidal output is desired, the MUX 403 and its connections (i.e., all enclosed in the dotted line in FIG. 4) are not implemented. Regardless of the implementation selected, after spur reduction is completed, a system may be designed to convert selectively only one or the other of the SIN out or COS out because a complex signal is not required and only one DAC would be specified.

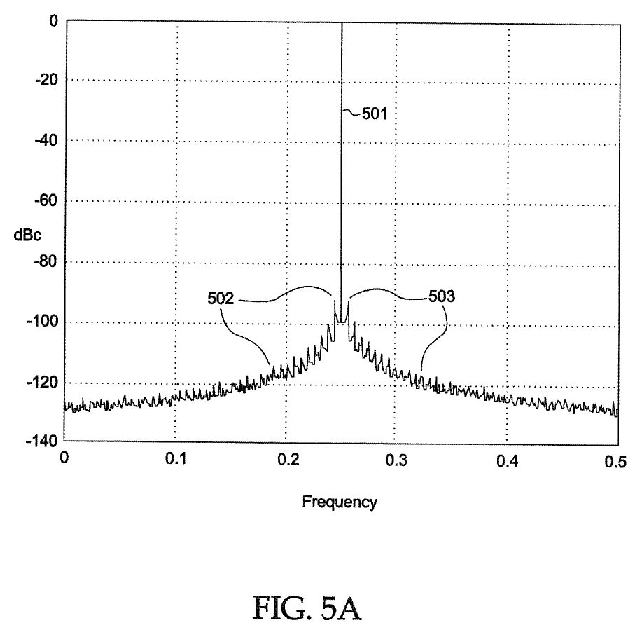

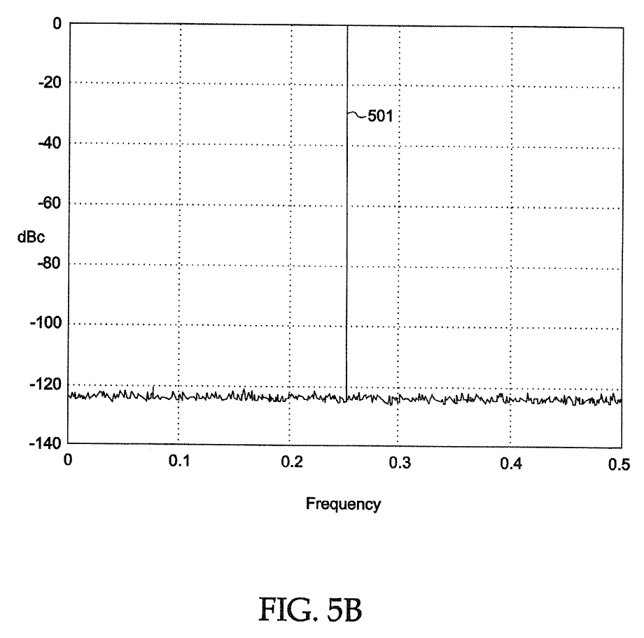

FIG. 5A is a graphical representation of a signal (power relative to the carrier power (dBc) versus normalized frequency) of a signal synthesized using a known DDS apparatus. In this example, the input frequency is set to a so called cardinal value whereby no alteration of the N-bit output value occurs when truncated to P bits (i.e. the LSBs are all zeros). The phase word from the phase accumulator is a 10 bit word. The desired frequency component is shown at 501. Even though in this example, no phase truncation spurs are present, nevertheless spurs 502,503 result from the repetitive accessing of the ROM amplitude values based on the phase values from the phase accumulator.

FIG. 5B shows a frequency spectrum of a DDS signal synthesized using a DDS method and apparatus in accordance with a representative embodiment. Like the example in FIG. 5A, a cardinal frequency value has been chosen and the phase word from the phase accumulator is a 10 bit word. The desired frequency 501 is again shown, however, spurs due to finite arithmetic effects in look up tables are substantially eliminated by random rotation in the phase domain and corresponding counter rotation in the amplitude domain. The resulting phase noise degradation is minimal, being only that energy that was originally contained in the spurious signal now spread uniformly over the sample spectrum and with no additional noise power added by the apparatus.

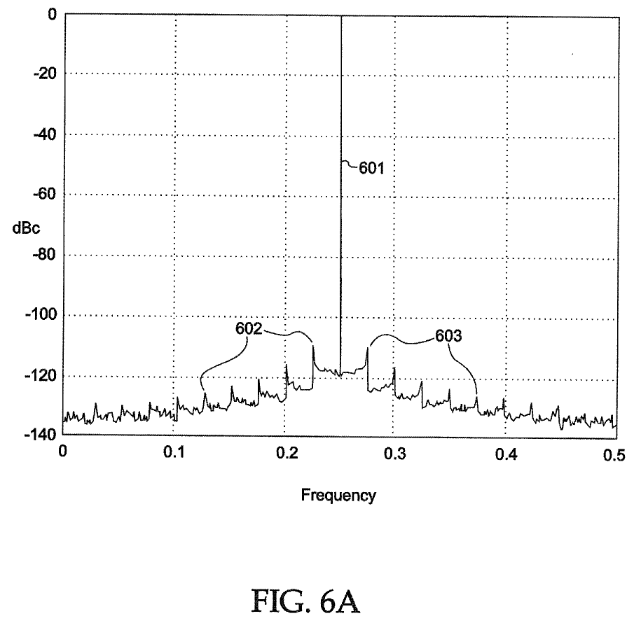

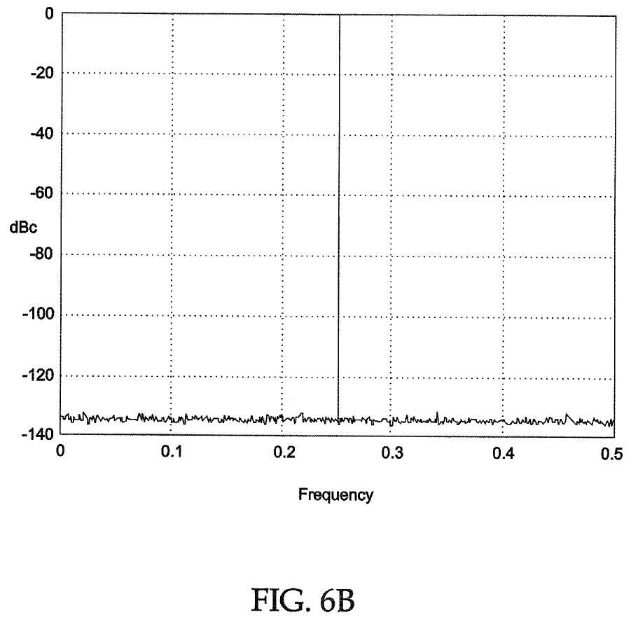

FIG. 6A is a graphical representation of a signal (power relative to the carrier power (dBc) versus normalized frequency) of a signal synthesized using a known DDS apparatus set to a 12-bit cardinal frequency. In this example, the phase word from the phase accumulator is a 12 bit word without deleterious effects from phase truncation. The desired frequency component is shown at 601. However, spurs 602,603 result from the repetitive accessing of the ROM amplitude values based on the phase values from the phase accumulator.

FIG. 6B shows a frequency spectrum of a DDS signal synthesized using a DDS method and apparatus in accordance with a representative embodiment. Like the example in FIG. 6A, a cardinal frequency is chosen and the phase word from the phase accumulator is a 12 bit word. The desired frequency 601 is again shown; however, spurs due to finite arithmetic effects in look up tables are substantially eliminated by random rotation in the phase domain and corresponding counter rotation in the amplitude domain. The resulting phase noise degradation is minimal, being only that energy that was originally contained in the spurious signal now spread uniformly over the sample spectrum and with no additional noise power added by the apparatus.

In view of this disclosure it is noted that the methods and devices can be implemented in keeping with the present teachings. Further, the various components, devices, structures and parameters are included by way of illustration and example only and not in any limiting sense. In view of this disclosure, the present teachings can be implemented in other applications and components, devices, structures and equipment to needed implement these applications can be determined, while remaining within the scope of the appended claims.

1. An apparatus, comprising:
a phase accumulator configured to provide an output comprising a truncated phase word representative of an instantaneous phase;
a multiplexer configured to provide an output representative of a phase rotation, wherein the output representative of the phase rotation is randomly selected from a group of phase rotation representation outputs;
an adder configured to receive the output from the phase accumulator and the output from the multiplexer, wherein the adder provides an output representative of the instantaneous phase rotated by the phase rotation;
a lookup table configured to receive the output representative of the instantaneous phase or a functional transformation thereof and to provide an amplitude output; and
a rotator configured to receive the amplitude output and substantially to cancel the phase rotation.

2. An apparatus as claimed in claim 1, wherein the phase accumulator comprises an adder and a delay element, and the delay element provides N bits to the adder, and the output comprising the truncated phase word comprise P bits, where N<P and N and P are real integers.

3. An apparatus as claimed in claim 1, wherein the outputs from the multiplexer are representative of one of: a positive quarter cycle phase rotation; a negative quarter cycle phase rotation; a zero phase rotation; and a half cycle phase rotation.

4. An apparatus as claimed in claim 1, further comprising a random number generator configured to provide an output to the multiplexer for the random selection of the phase rotation.

5. An apparatus as claimed in claim 1, wherein the lookup table comprises a sinusoidal lookup table and a cosinusoidal lookup table.

6. An apparatus as claimed in claim 5, wherein the amplitude output comprises a quadrature output.

7. An apparatus as claimed in claim 1, wherein the rotator comprises a complex multiplier.

8. An apparatus as claimed in claim 1, wherein the rotator is configured to provide a plurality of outputs, each representative of an amplitude of a signal at a particular phase, wherein the signal is substantially free of spurious signals due to truncation errors.

9. An apparatus, comprising:
a phase accumulator configured to provide an output comprising a truncated phase word representative of an instantaneous phase;
a multiplexer configured to provide an output representative of a phase rotation, wherein the output representative of the phase rotation is randomly selected from a group of phase rotation representation outputs;
an adder configured to receive the output from the phase accumulator and the output from the multiplexer, wherein the adder provides an output representative of the instantaneous phase rotated by the phase rotation;
a lookup table configured to receive the output representative of the instantaneous phase or a functional transformation thereof and to provide an amplitude output;
a first output multiplexer configured to receive the amplitude output and to substantially cancel the phase rotation; and
a second output multiplexer configured to receive the amplitude output and to substantially cancel the phase rotation.

10. An apparatus as claimed in claim 9, wherein the phase accumulator comprises an adder and a delay element, and the delay element provides N bits to the adder, and the output comprising the truncated phase word comprise P bits, where N<P and N and P are real integers.

11. An apparatus as claimed in claim 9, wherein the outputs from the multiplexer are representative of one of: a positive quarter cycle phase rotation; a negative quarter cycle phase rotation; a zero phase rotation; and a half cycle phase rotation.

12. An apparatus as claimed in claim 9, further comprising a random number generator configured to provide an output to the multiplexer for the random selection of the phase rotation.

13. An apparatus as claimed in claim 9, wherein the first output multiplexer, or the second output multiplexer, or both is configured to provide a plurality of outputs, each representative of an amplitude of a signal at a particular phase, wherein the signal is substantially free of spurious signals due to truncation errors.

14. In an apparatus comprising a phase accumulator, an adder, a multiplexer and a lookup table, a method, comprising:
providing an output from the phase accumulator which comprises a truncated phase word representative of an instantaneous phase;
providing an output representative of a phase rotation from the multiplexer, wherein the output representative of the phase rotation is randomly selected from a group of phase rotation representation outputs;
receiving the output from the phase accumulator and the output from the multiplexer;
adding the output from the phase accumulator and the output from the multiplexer to provide an output representative of the instantaneous phase rotated by the phase rotation;
converting the instantaneous phase and to an amplitude; and
cancelling the random phase rotation.
wherein the phase accumulator comprises an adder and a delay element, and the delay element provides N bits to the adder, and the output comprising the truncated phase word comprise P bits, where N<P and N and P are real integers.

15. A method as claimed in claim 14, wherein the outputs from the multiplexer are representative of one of: a positive quarter cycle phase rotation; a negative quarter cycle phase rotation; a zero phase rotation; and a half cycle phase rotation.

16. A method as claimed in claim 14, further comprising a random number generator configured to provide an output to the multiplexer for the random selection of the phase rotation.

17. A method as claimed in claim 14, wherein the lookup table comprises a sinusoidal lookup table and a cosinusoidal lookup table.

18. A method as claimed in claim 17, wherein the amplitude output comprises a quadrature output.
